(19) United States
(12) Patent Application Publication
(10) Pub. No.: US 2017/0271175 A1
(43) Pub. Date: Sep. 21, 2017

(54) EXPOSED DIE MOLD UNDERFILL (MUF) WITH FINE PITCH COPPER (CU) PILLAR ASSEMBLY AND BUMP DENSITY

(71) Applicant: QUALCOMM Incorporated, San Diego, CA (US)

(72) Inventors: Christopher James HEALY, San Diego, CA (US); John Patrick HOLMES, San Diego, CA (US); Michael James SOLIMANDO, San Diego, CA (US); Sun YUN, San Diego, CA (US); William Michael STONE, San Diego, CA (US); Rajendra PENDSE, Fremont, CA (US)

(21) Appl. No.: 15/460,062

(22) Filed: Mar. 15, 2017

Related U.S. Application Data
(60) Provisional application No. 62/309,409, filed on Mar. 16, 2016.

(51) Int. Cl. H01L 21/56; H01L 23/00; H01L 23/498

(52) U.S. Cl. CPC H01L 21/563; H01L 21/565; H01L 23/49816; H01L 23/49827; H01L 24/14; H01L 24/13; H01L 24/16; H01L 2924/1816; H01L 2224/13147; H01L 2224/14131; H01L 2224/16235

(57) ABSTRACT

Disclosed is a die packaging structure comprising a semiconductor die, an encapsulant layer disposed around the semiconductor die, wherein a backside surface of the semiconductor die is exposed, and a conductive layer coupled to the semiconductor die, the conductive layer comprising a plurality of conductive pillar bumps, wherein a bump density of the plurality of conductive pillar bumps is greater than 5%, wherein the encapsulant layer is further disposed between the plurality of conductive bumps, and wherein the encapsulant layer is disposed between the plurality of conductive bumps using a mold underfill (MUF) process. A method of forming the same is also disclosed.

### CROSS-REFERENCE TO RELATED APPLICATIONS

The present Application for Patent claims the benefit of U.S. Provisional Application No. 62/309,409, entitled “EXPOSED DIE MOLD UNDERFILL (MUF) WITH FINE PITCH COPPER (CU) PILLAR ASSEMBLY AND BUMP DENSITY,” filed Mar. 16, 2016, assigned to the assignee hereof, and expressly incorporated herein by reference in its entirety.

### INTRODUCTION

Aspects relate to exposed die mold underfill (MUF) with fine pitch copper (Cu) pillar assembly and bump density.

Semiconductor device fabrication is the process used to create the integrated circuits that are present in everyday electrical and electronic devices. It is a multiple-step sequence of photo lithographic and chemical processing steps during which electronic circuits are gradually created on a wafer made of pure semiconducting material.

Exposed die packaging, where the backside of a semiconductor die (e.g., an integrated circuit (IC), a digital signal processor (DSP), an application specific integrated circuit (ASIC), a field programmable gate array (FPGA), or other programmable logic device) is exposed rather than covered by an encapsulant (as in overmold packaging), is a popular solution for packaging semiconductor dies, as it provides greater thermal dissipation and a lower profile than overmold packaging. An exposed die package generally includes an insulating layer, a conductive layer (e.g., copper (Cu) pillar bumps or solder bumps) that forms the input/output (I/O) connections of the semiconductor die, and package balls. An encapsulant, or molding compound, is deposited over the semiconductor die. Vias in the insulating layer connect the package balls to the conductive layer of the semiconductor die.

Where the conductive layer comprises Cu pillar bumps, before the encapsulant is molded onto the exposed die package, the conductive layer is protected using the capillary underfill (CUF) process. This protection is important because the exposed die molding process imparts physical stress on the semiconductor die, and thus the Cu pillar bumps of the conductive layer, through the act of molding itself. For example, the clamping and transfer pressures involved in the molding process can damage the Cu pillar bumps. The act of protecting the conductive layer prior to molding shields the conductive layer from the stresses imposed on it during the exposed die molding process.

The CUF process introduces additional steps in the fabrication process and thus, where the conductive layer is made up of solder bumps, which are larger and therefore stronger than Cu pillar bumps, the CUF process can be skipped. Instead, during the molding process, the encapsulant is forced between the solder bumps of the conductive layer. This is referred to as the mold underfill (MUF) process.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a die packaging structure includes a semiconductor die, an encapsulant layer disposed around the semiconductor die, wherein a backside surface of the semiconductor die is exposed, and a conductive layer coupled to the semiconductor die, the conductive layer comprising a plurality of conductive pillar bumps, wherein a bump density of the plurality of conductive pillar bumps is greater than 5%, wherein the encapsulant layer is further disposed between the plurality of conductive bumps, and wherein the encapsulant layer is disposed between the plurality of conductive bumps using a mold underfill (MUF) process.

In an aspect, a method of forming a die packaging structure includes providing a semiconductor die, forming a conductive layer coupled to the semiconductor die, the conductive layer comprising a plurality of conductive pillar bumps, wherein a bump density of the plurality of conductive pillar bumps is greater than 5%, and forming an encapsulant layer around the semiconductor die, wherein a backside surface of the semiconductor die is exposed, and wherein forming the encapsulant layer further comprises inserting the encapsulant layer between the plurality of conductive bumps using a MUF process.

In an aspect, an apparatus includes a semiconductor means, means for encapsulating disposed around the semiconductor means, wherein a backside surface of the semiconductor means is exposed, and a means for conducting coupled to the semiconductor means, the means for conducting comprising a plurality of conductive pillar bumps, wherein a bump density of the plurality of conductive pillar bumps is greater than 5%, wherein the means for encapsulating is further disposed between the plurality of conductive bumps, and wherein the means for encapsulating is disposed between the plurality of conductive bumps using MUF process.

In an aspect, a non-transitory computer-readable medium storing computer-executable instructions for forming a die packaging structure includes computer-executable instructions comprising at least one instruction for causing a machine to provide a semiconductor die, at least one instruction for causing a machine to form a conductive layer coupled to the semiconductor die, the conductive layer comprising a plurality of conductive pillar bumps, wherein a bump density of the plurality of conductive pillar bumps is greater than 5%, and at least one instruction for causing a machine to form an encapsulant layer around the semiconductor die, wherein a backside surface of the semiconductor die is exposed, and wherein the at least one instruction for causing a machine to form the encapsulant layer comprises at least one instruction for causing a machine to insert the encapsulant layer between the plurality of conductive bumps using a MUF process.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure will be readily obtained as the same becomes better understood by reference to the following detailed description when considered in connection with the accompanying drawings, which are presented solely for illustration and not limitation of the disclosure, and in which:

FIG. 1 illustrates an exemplary exposed die packaging structure.

FIGS. 2A and 2B illustrate the differences between the capillary underfill (CUF) process (FIG. 2A) and the mold underfill (MUF) process (FIG. 2B).

FIG. 3 illustrates an exemplary high-level CUF fabrication process.

FIG. 4 illustrates an exemplary high-level MUF fabrication process.

FIG. 5 illustrates damage to a copper (Cu) pillar bump that can be caused during the MUF process if the aspects of the disclosure are not implemented.

FIGS. 6A and 6B illustrate an exemplary exposed die packaging structure according to at least one aspect of the disclosure.

FIG. 7 illustrates an exemplary method for forming an exposed die packaging structure.

### DETAILED DESCRIPTION

Disclosed is a die packaging structure comprising a semiconductor die, an encapsulant layer disposed around the semiconductor die, wherein a backside surface of the semiconductor die is exposed, and a conductive layer coupled to the semiconductor die, the conductive layer comprising a plurality of conductive pillar bumps, wherein a bump density of the plurality of conductive pillar bumps is greater than 5%, wherein the encapsulant layer is further disposed between the plurality of conductive bumps, and wherein the encapsulant layer is disposed between the plurality of conductive bumps using a mold underfill (MUF) process.

Also disclosed is a method of forming a die packaging structure including providing a semiconductor die, forming a conductive layer coupled to the semiconductor die, the conductive layer comprising a plurality of conductive pillar bumps, wherein a bump density of the plurality of conductive pillar bumps is greater than 5%, and forming an encapsulant layer around the semiconductor die, wherein a backside surface of the semiconductor die is exposed, and wherein the encapsulant layer is inserted between the plurality of conductive bumps, and wherein the encapsulant layer is inserted between the plurality of conductive bumps using a MUF process.

These and other aspects of the disclosure are disclosed in the following description and related drawings directed to specific aspects of the disclosure. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Semiconductor device fabrication is the process used to create the integrated circuits that are present in everyday electrical and electronic devices. It is a multiple-step sequence of photo lithographic and chemical processing steps during which electronic circuits are gradually created on a wafer made of pure semiconducting material.

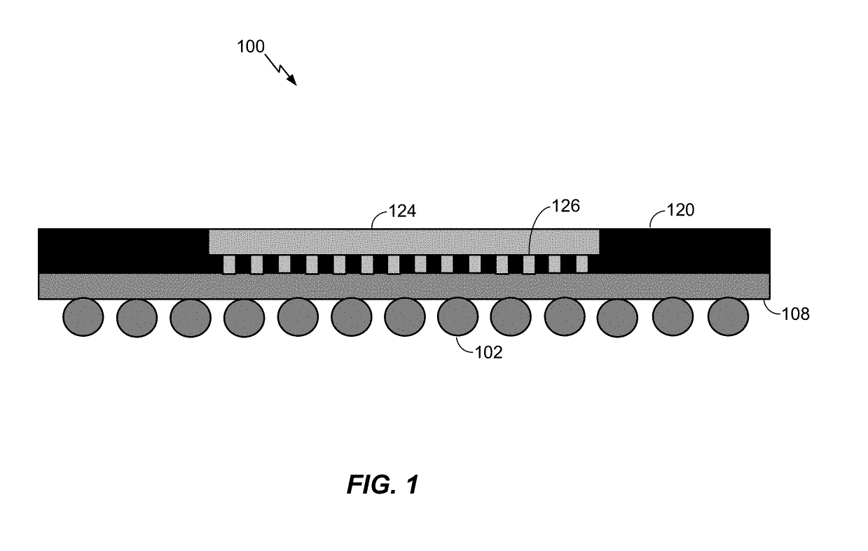

Exposed die packaging, where the backside of a semiconductor die is exposed rather than covered by an encapsulant (as in overmold packaging), is a popular solution for packaging semiconductor dies, as it provides greater thermal dissipation and a lower profile than overmold packaging. FIG. 1 illustrates an exemplary exposed die packaging structure 100. The exposed die packaging structure 100 includes an insulating layer 108, a conductive layer 126, and package balls 102. An encapsulant 120, or molding compound, is deposited over a semiconductor die 124. The conductive layer 126 may be, for example, copper (Cu) pillar bumps or solder bumps, and forms the input/output (I/O) connections of the semiconductor die 124. Vias (not shown) in the insulating layer 108 connect the package balls 102 to the conductive layer 126 of the semiconductor die 124.

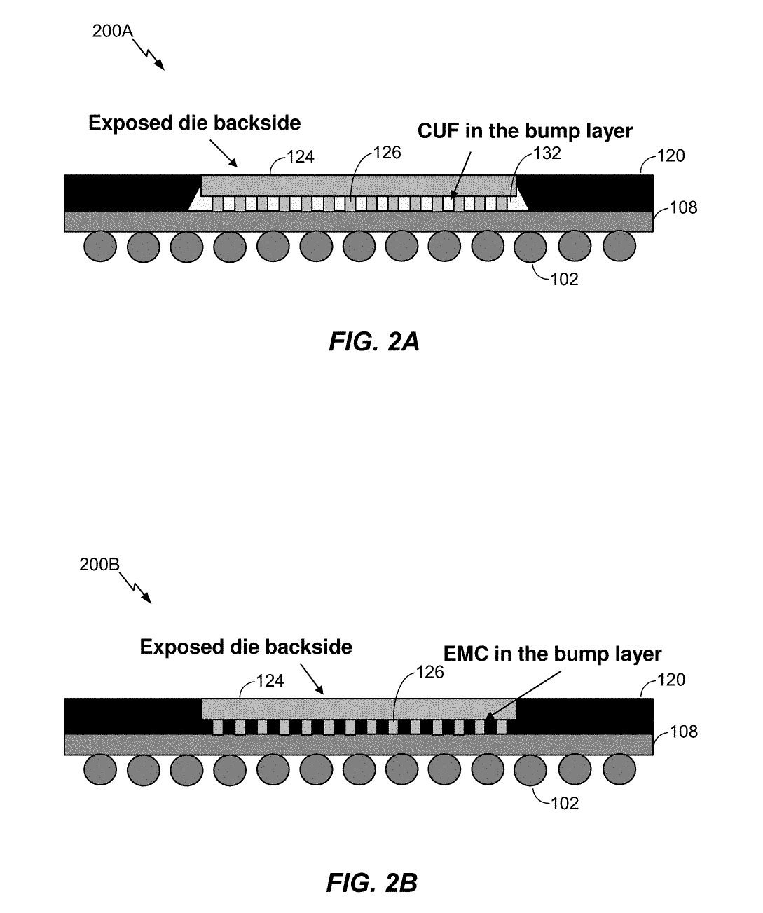

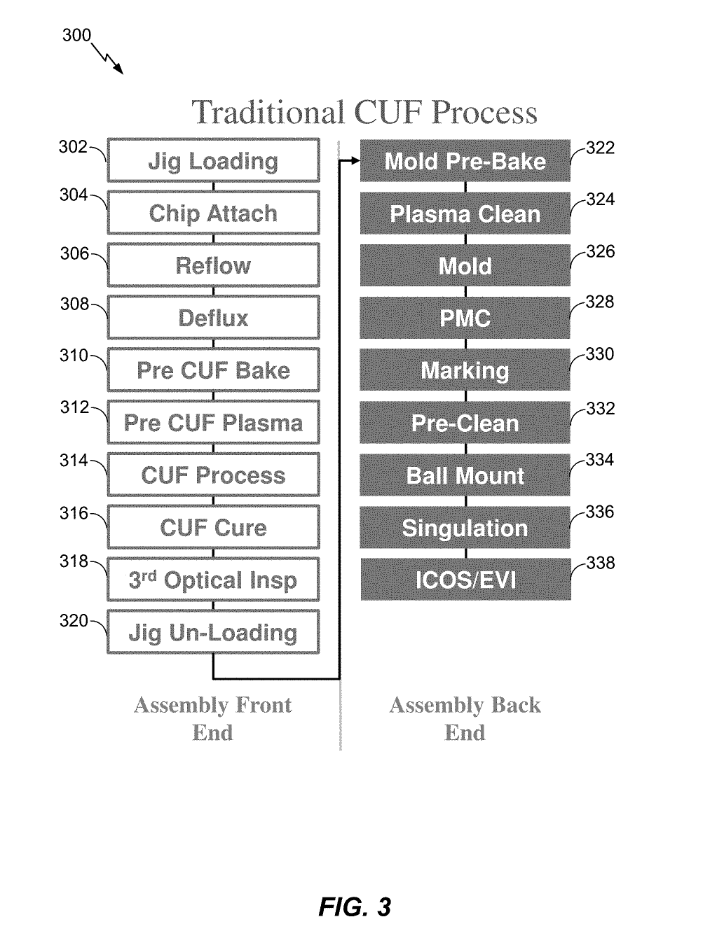

The insulating layer 108 may be one or more layers of silicon dioxide (SiO2), silicon nitride (Si3N4), silicon oxynitride (SiON), tantalum pentoxide (Ta2O5), aluminum oxide (A12O3), hafnium oxide (HfO2), benzocyclobutene (BCB), polyimide (PI), polybenzoxazoles (PBO), or other material having similar insulating and structural properties, as is known in the art. The conductive layer 126 may be one or more layers of aluminum (Al), copper (Cu), tin (Sn), nickel (Ni), gold (Au), silver (Ag), or other suitable electrically conductive material, as is known in the art. The package balls 102 may be Al, Cu, Sn, Ni, Au, Ag, lead (Pb), bismuth (Bi), solder, or combinations thereof, with an optional flux solution, as is known in the art. The encapsulant 120 may be a polymer composite material, such as epoxy resin with filler, epoxy acrylate with filler, or polymer with proper filler and is non-conductive, provides physical support, and environmentally protects the semiconductor die 124 from external elements and contaminants, as is known in the art. The semiconductor die 124 may be an integrated circuit (IC), a digital signal processor (DSP), an application specific integrated circuit (ASIC), a field programmable gate array (FPGA), or other programmable logic device.

Where the conductive layer 126 comprises Cu pillar bumps, before the encapsulant 120 is molded onto the exposed die packaging structure 100, the conductive layer 126 is protected using the capillary underfill (CUF) process (described below with reference to FIGS. 2A and 3). This protection is important because the process of molding the encapsulant 120 around the exposed semiconductor die 124 imparts physical stress on the semiconductor die 124, and thus the Cu pillar bumps of the conductive layer 126, through the act of molding itself. For example, the clamping and transfer pressures involved in the encapsulant molding process can damage the Cu pillar bumps of the conductive layer 126. The act of protecting the conductive layer 126 using the CUF process prior to the encapsulant molding process shields the conductive layer 126 from the stresses imposed on it during the process of molding the encapsulant 120 around the exposed semiconductor die 124.

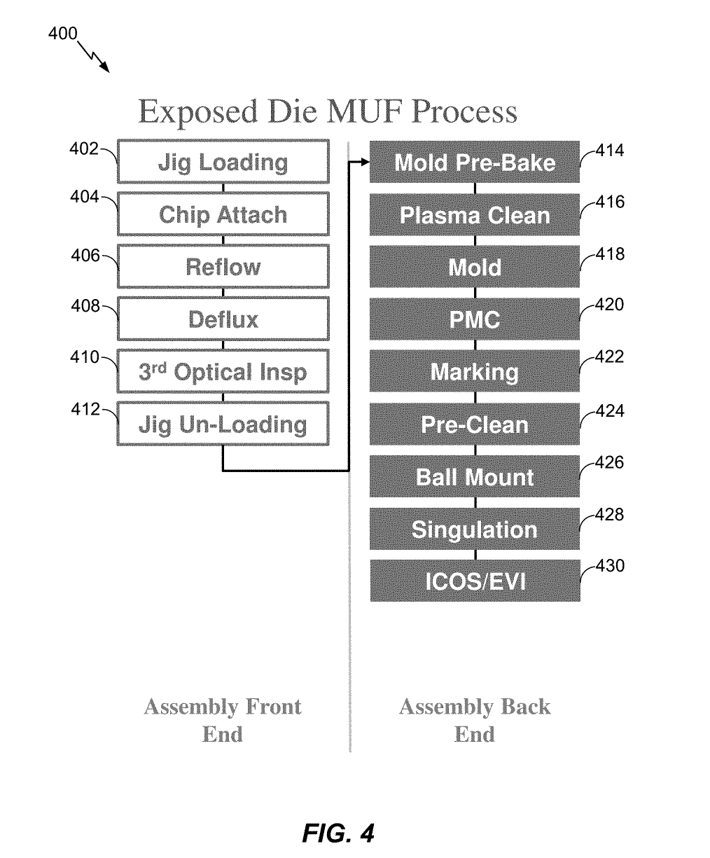

The CUF process introduces additional steps in the fabrication process and thus, where the conductive layer 126 is made up of solder bumps, which are larger and therefore stronger than Cu pillar bumps, the CUF process can be skipped. Instead, during the encapsulant molding process, the encapsulant 120 is simply forced between the solder bumps of the conductive layer 126. This is referred to as the mold underfill (MUF) process and is described further below with reference to FIGS. 2B and 4.

FIGS. 2A and 2B illustrate exemplary differences between the CUF process (FIG. 2A) and the MUF process (FIG. 2B). As illustrated in FIG. 2A and described further with reference to FIG. 3, in the CUF process, a CUF material 132 is formed around the Cu pillar bumps of the conductive layer 126 of the exposed die packaging structure 200A to protect the Cu pillar bumps from the subsequent encapsulant molding process (i.e., the process of molding the encapsulant 120 around the exposed semiconductor die 124). In contrast, as illustrated in FIG. 2B and described further with reference to FIG. 4, in the MUF process, the encapsulant 120 (referred to in the figure as “EMC” for “epoxy mold compound”) is simply forced under the semiconductor die 124 and around the solder bumps of the conductive layer 126 of the exposed die packaging structure 200B during the process of molding the encapsulant 120 around the exposed semiconductor die 124. Due to the larger size and therefore greater strength of the solder bumps, there is no need to protect the solder bumps from the encapsulant molding process, as there is when the conductive layer 126 comprises Cu pillar bumps.

FIG. 3 illustrates an exemplary exposed die fabrication process 300 utilizing the CUF process. At 302, a strip of wafer is loaded into the jig. At 304, the semiconductor dies, such as semiconductor die 124, are attached to the wafer strip. At 306, the wafer strip is heated to reflow the solder attachment points between the semiconductor dies and the connection points on the wafer strip. At 308, the wafer strip is cleaned with a deflux solution. At 310, the wafer strip undergoes a pre-CUF “bake” to remove any remaining water from the deflux cleaning performed at 308. At 312, the wafer strip undergoes a plasma clean to prepare it for the CUF process. At 314, the CUF process is performed. Specifically, the CUF material, such as CUF material 132, is placed around the semiconductor dies on the wafer strip and, during the process, is “pulled” under the semiconductor dies by capillary action. At 316, the CUF material is cured. At 318, a third optical inspection is performed (the first two optical inspections are not illustrated in FIG. 3). At 320, the wafer strip is unloaded from the jig.

At 322, the wafer strip undergoes a pre-mold bake, and at 324, is plasma cleaned. At 326, the encapsulant molding process is performed by compressing a molding compound, such as encapsulant 120, onto the wafer strip and around the semiconductor dies. At 328, the wafer strip undergoes a post-mold cure (PMC) to finish hardening the molding compound. At 330, the wafer strip is laser marked with part number, lot number, etc. At 332, the bottom side of the wafer strip is cleaned to prepare it for the package balls, such as package balls 102, to be mounted. At 334, the package balls are mounted to the wafer strip. At 336, the wafer strip is singulated into individual units (e.g., one semiconductor die per unit, as illustrated in FIG. 1). At 338, the individual units are inspected using, for example, ICOS/EVI.

FIG. 4 illustrates an exemplary exposed die fabrication process 400 utilizing the MUF process. At 402, a strip of wafer is loaded into the jig. At 404, the semiconductor dies, such as semiconductor die 124, are attached to the wafer strip. At 406, the wafer strip is heated to reflow the solder attachment points between the semiconductor dies and the connection points on the wafer strip. At 408, the wafer strip is cleaned with a deflux solution. In contrast to the exposed die fabrication process 300 in FIG. 3, the exposed die fabrication process 400 skips the CUF process (operations 310 to 316 in FIG. 3) and proceeds to 410, where a third optical inspection is performed (the first two optical inspections are not illustrated in FIG. 4). At 412, the wafer strip is unloaded from the jig.

At 414, the wafer strip undergoes a pre-mold bake, and at 416, is plasma cleaned. At 418, the encapsulant molding process is performed by compressing a molding compound, such as encapsulant 120, onto the wafer strip and around the semiconductor dies. At 420, the wafer strip undergoes a post-mold cure (PMC) to finish hardening the molding compound. At 422, the wafer strip is laser marked with part number, lot number, etc. At 424, the bottom side of the wafer strip is cleaned to prepare it for the package balls, such as package balls 102, to be mounted. At 426, the package balls are mounted to the wafer strip. At 428, the wafer strip is singulated into individual units (e.g., one semiconductor die per unit, as illustrated in FIG. 1). At 430, the individual units are inspected using, for example, ICOS/EVI.

The MUF process, which can be performed when the conductive layer 126 comprises solder bumps, is generally preferable to the CUF process, which is performed when the conductive layer 126 comprises Cu pillar bumps, because of its reduced manufacturing cycle (i.e., it does not include the CUF process operations 310 to 316 in FIG. 3) and therefore lower cost. Using Cu pillar bumps as the conductive layer 126 is preferable, however, because, due to their smaller size compared to solder bumps, there can be more Cu pillar bumps in the conductive layer 126 to provide input/output connections for the semiconductor die 124 than there could be solder bumps. However, because Cu pillar bumps are smaller, and therefore weaker, than solder bumps, using the MUF process when the conductive layer 126 comprises Cu pillar bumps would damage the Cu pillar bumps due to the stresses imposed on the conductive layer 126 during the encapsulant molding process (e.g., 418 of FIG. 4) of the MUF process. As such, the current exposed die packaging approach for semiconductor dies having Cu pillar bumps as the conductive layer 126 is to protect the conductive layer 126 using the CUF process (e.g., operations 310 to 316 in FIG. 3) before the encapsulant molding process (e.g., operation 326 in FIG. 3 and operation 418 in FIG. 4).

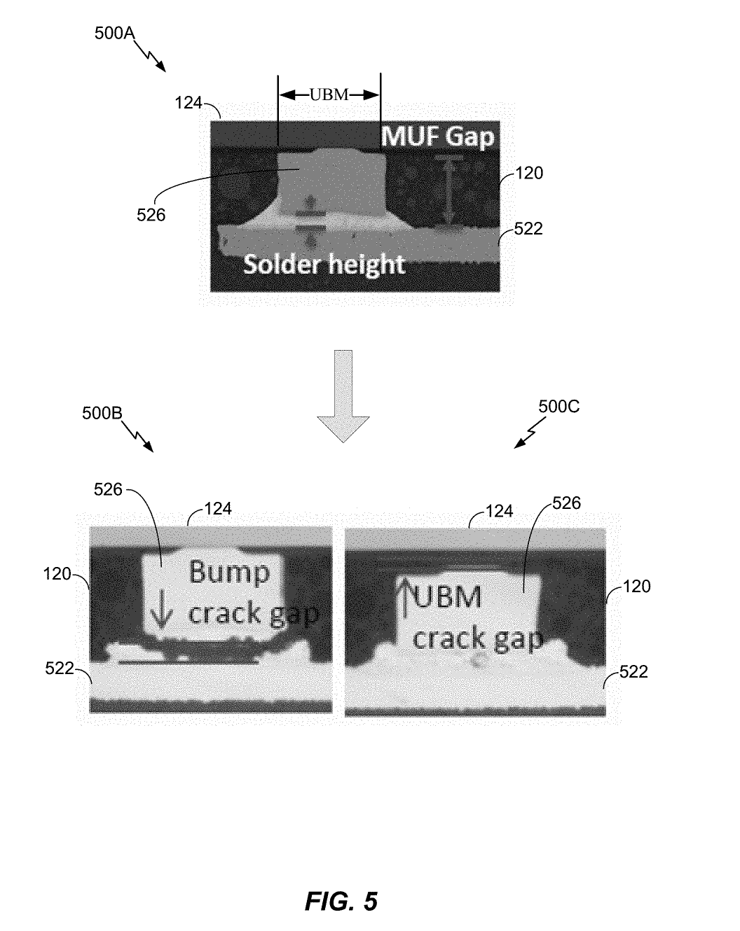

FIG. 5 illustrates damage to a Cu pillar bump 526 that could be caused during the MUF process if the aspects of the disclosure described below are not implemented. In FIG. 5, the cross-section 500A illustrates an undamaged Cu pillar bump 526. In the cross-section 500A, the MUF gap (i.e., the distance between the semiconductor die 124 and the conductive layer 522 (e.g., the “trace”) to which the Cu pillar bump 526 is attached), the solder height (i.e., the height of the solder attaching the Cu pillar bump 526 to the conductive layer 522), and the under-bump metallization (UBM) are labeled. The MUF gap is preferably filled with encapsulant 120. The UBM is the area of the top of the Cu pillar bump 526.

The cross-section 500B illustrates the Cu pillar bump 526 exhibiting a “bump crack” gap. A “bump crack” occurs when the solder attaching the Cu pillar bump 526 to the conductive layer 522 cracks or breaks, resulting in a gap between the Cu pillar bump 526 and the conductive layer 522. This can be caused by the pressure of the molding compound (e.g., the encapsulant 120) on the semiconductor die 124 as the molding compound is injected under the semiconductor die 124 and around the Cu pillar bump 526.

The cross-section 500C illustrates the Cu pillar bump 526 exhibiting a “UBM crack” gap. A “UBM crack” occurs when the joint between the Cu pillar bump 526 and the semiconductor die 124 cracks or breaks, resulting in a gap between the Cu pillar bump 526 and the semiconductor die 124. This can also be caused by the pressure of the molding compound (e.g., the encapsulant 120) on the semiconductor die 124 as the molding compound is injected under the semiconductor die 124 and around the Cu pillar bump 526.

Because of the advantages of both the MUF process and using Cu pillar bumps as the conductive layer 126 of the semiconductor die 124, it would be beneficial to be able to use the MUF process in fabricating exposed die packages having Cu pillar bumps as the conductive layer 126.

There is a given density for the Cu pillar bumps of the conductive layer 126 that can prevent damage to the Cu pillar bumps when using the MUF process. Specifically, a Cu pillar bump density greater than 5% (and generally less than 10%) provides an optimal density to prevent damage to the Cu pillar bumps of the conductive layer 126. With a Cu pillar bump density of 5-10%, injecting the molding compound (e.g., the encapsulant 120) into the MUF gap does not cause the damage to the Cu pillar bumps of the conductive layer 126 illustrated in FIG. 5.

As used herein, the “bump density” is the Total Bump Area divided by the Die Area. The Total Bump Area is the number of Cu pillar bumps under the semiconductor die 124 multiplied by the UBM Area. The UBM Area is the cross-sectional area of the “top” of a Cu pillar bump, that is, the area of a Cu pillar bump where it connects to the semiconductor die 124 (see e.g., the cross-section 500A in FIG. 5). The UBM Area may be any shape (e.g., circular, oblong, square, rectangular, etc.). The Die Area is the area on the wafer strip of the semiconductor die 124, which is calculated by multiplying the length and width dimensions of the semiconductor die 124.

Note that the center-to-center distance between Cu pillar bumps of the conductive layer 126 is referred to as the “pitch” of the Cu pillar bumps. In an aspect, the Cu pillar bumps of the conductive layer 126 may be evenly distributed under the semiconductor die 124, meaning that the center-to-center distance between each Cu pillar bump is the same. However, this is not necessary, and the center-to-center distances between Cu pillar bumps may be different.

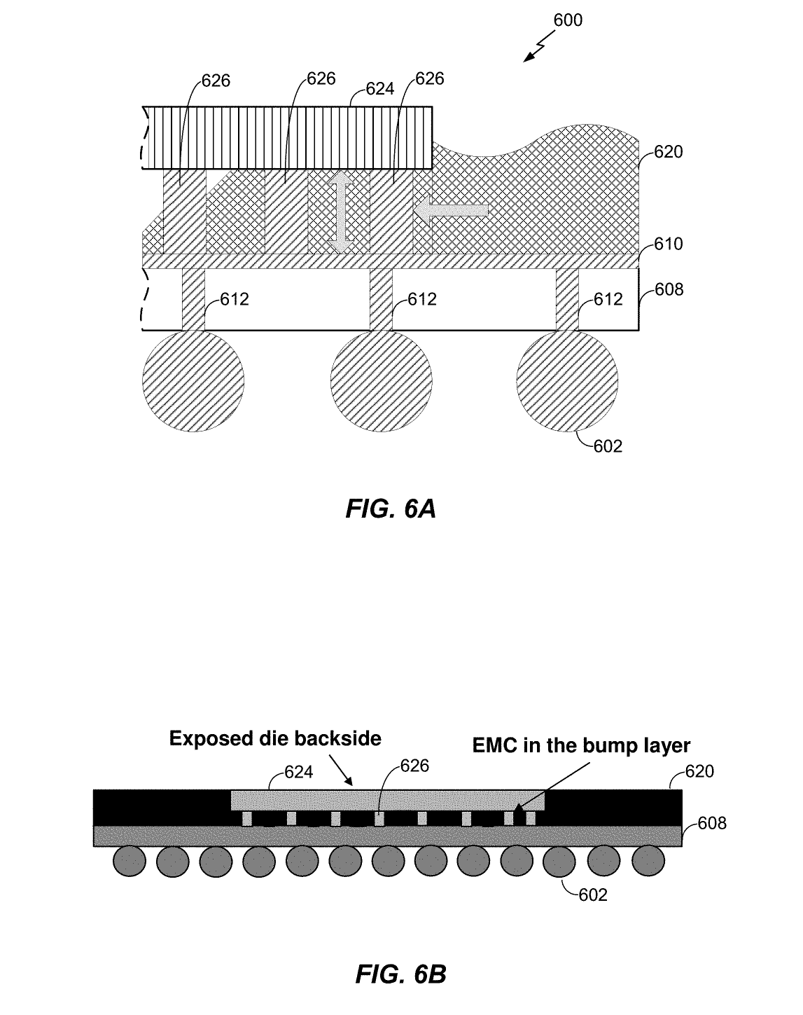

FIGS. 6A and 6B illustrate an exemplary exposed die packaging structure 600 according to at least one aspect of the disclosure. In the example of FIGS. 6A and 6B, the exposed die packaging structure 600 includes a semiconductor die 624, similar to the semiconductor die 124, an insulating layer 608, similar to the insulating layer 108, package balls 602, similar to package balls 102, an encapsulant 620, similar to the encapsulant 120, and a conductive layer 626, similar to the conductive layer 126. However, in contrast to the conductive layer 126, the conductive layer 626 comprises a plurality of Cu pillar bumps having a bump density greater than 5%. As further illustrated in FIG. 6A, the Cu pillar bumps of the conductive layer 626 are conductively coupled to conductive traces 610 formed on the insulating layer 608. Vias 612 in the insulating layer 608 conductively connect the conductive traces 610, and thereby the Cu pillar bumps of the conductive layer 626, to the package balls 602.

FIG. 6A is a close-up view of the exposed die packaging structure 600 illustrating exemplary forces on the semiconductor die 624, the Cu pillar bumps of the conductive layer 626, and the insulating layer 608 as the encapsulant 620 is injected during the MUF process. Specifically, during the MUF process, the encapsulant 620 (e.g., EMC) is forced under the semiconductor die 624 and around the Cu pillar bumps of the conductive layer 626, resulting in the encapsulant 620 surrounding the semiconductor die 624 and the Cu pillar bumps of the conductive layer 626. The backside of the semiconductor die 624 remains exposed after this process.

The arrows in FIG. 6A illustrate that injection of the encapsulant 620 causes sideways pressure on the Cu pillar bumps of the conductive layer 626, upward pressure on the semiconductor die 624, and downward pressure on the insulating layer 608. Normally, this pressure would cause the type of damage to the Cu pillar bumps illustrated in FIG. 5. However, because the bump density of the Cu pillar bumps of the conductive layer 626 is greater than 5% (and optionally less than 10%), performing the MUF process on the exposed die packaging structure 600 will not cause the damage to the Cu pillar bumps illustrated in FIG. 5.

FIG. 6B illustrates a view of the exemplary exposed die packaging structure 600 after the encapsulant 620 has been injected during the MUF process. For simplicity, the conductive traces 610 and vias 612 are not shown in FIG. 6B. As illustrated in FIG. 6B, the encapsulant 620 has been forced under the semiconductor die 624 and around the Cu pillar bumps of the conductive layer 626. As discussed above with reference to FIG. 6A, because the bump density of the Cu pillar bumps of the conductive layer 626 is greater than 5%, performing the MUF process on the exposed die packaging structure 600 will not cause the damage to the Cu pillar bumps illustrated in FIG. 5.

It should be noted that a bump density greater than 5% does not mean that the bump density cannot be less than or equal to 5%. Rather, the bump density may be within some tolerance threshold of 5%. Similarly, a bump density of less than 10% does not mean that the bump density cannot be greater than or equal to 10%. Rather, the bump density may be within some tolerance threshold of 10%.

For example, although a given exposed die packaging structure may have been designed with a bump density greater than 5%, due to the tolerances permitted in manufacturing the components of the exposed die packaging structure, the bump density of the exposed die packaging structure that is actually manufactured may not be greater than 5%, but rather, may be within some tolerance threshold of 5%.

Similarly, as another example, although a given exposed die packaging structure may have been designed with a bump density less than 10%, due to the tolerances permitted in manufacturing the components of the exposed die packaging structure, the bump density of the exposed die packaging structure that is actually manufactured may not be less than 10%, but rather, may be within some tolerance threshold of 10%.

Further, as noted above, the center-to-center distance between Cu pillar bumps is referred to as the “pitch” of the Cu pillar bumps. In an aspect, the Cu pillar bumps of the conductive layer 626 may be evenly distributed under the semiconductor die 624, meaning that the center-to-center distance between each Cu pillar bump is the same. However, this is not necessary, and the center-to-center distances between Cu pillar bumps may be different. Note that although a given exposed die packaging structure may have been designed with a certain pitch, due to the tolerances permitted in manufacturing the components of the exposed die packaging structure, the center-to-center distance between each Cu pillar bump of the exposed die packaging structure that is actually manufactured may not be exactly the same, but rather, may be within some tolerance threshold of the desired pitch.

It will be appreciated that various aspects disclosed herein can be described as functional equivalents to the structures described and recognized by those skilled in the art. For example, in one aspect, an apparatus may comprise a semiconductor means (see, e.g., 624 in FIG. 6), a means for encapsulating, or an encapsulant means (see, e.g., 620 in FIG. 6), disposed around the semiconductor means, wherein a backside surface of the semiconductor means is exposed. Such an apparatus may further include a means for conducting (e.g., conductive layer 626) coupled to the semiconductor means, the means for conducting comprising a plurality of conductive pillar bumps, wherein a bump density of the plurality of conductive pillar bumps is greater than 5%. The means for encapsulating, or encapsulant means, may be further disposed between the plurality of conductive bumps using a MUF process. It will be appreciated that the aforementioned aspects are merely provided as examples and the various aspects claimed are not limited to the specific references and/or illustrations cited as examples.

It will also be appreciated that computer-executable instructions to cause one or more machines to manufacture an exposed die packaging structure, such as the exposed die packaging structure 600, may be stored on a computer-readable medium. Computer-readable media includes both non-transitory computer storage media and/or communication media including any medium that facilitates transfer of a computer program from one place to another. A storage media may be any available media that can be accessed by a computer. By way of example, and not limitation, such computer-readable media can comprise random access memory (RAM), read-only memory (ROM), electrically erasable programmable ROM (EEPROM), CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital video disc (DVD), floppy disk, and/or Blu-ray disc, where disks usually reproduce data magnetically and/or optically with lasers. Combinations of the above should also be included within the scope of computer-readable media.

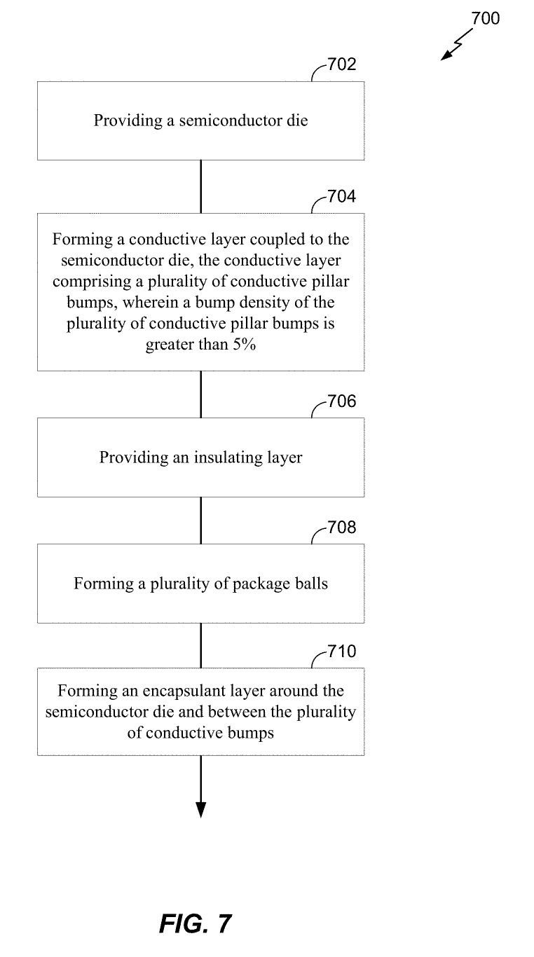

For example, with reference to FIG. 7, a computer-readable medium may store computer-executable instructions that, when executed, may cause one or more manufacturing machines to perform a method 700 for forming an exposed die packaging structure. The method 700 may include providing, at 702, a semiconductor die (e.g., semiconductor die 624), forming, at 704, a conductive layer (e.g., conductive layer 626) coupled to the semiconductor die, the conductive layer comprising a plurality of conductive (e.g., Cu) pillar bumps having a bump density greater than 5%, providing, at 706, an insulating layer (e.g., insulating layer 608) coupled to the conductive layer, forming, at 708, a plurality of package balls (e.g., package balls 602) coupled to the insulating layer, and forming, at 710, an encapsulant layer (e.g., encapsulant 620) around the semiconductor die and between the plurality of conductive bumps.

In an aspect, as described above, the bump density of the plurality of conductive pillar bumps being greater than 5% may mean that the bump density of the plurality of conductive pillar bumps is within a tolerance threshold of 5%. In an aspect, the bump density of the plurality of conductive pillar bumps may be less than 10%. As described above, the bump density of the plurality of conductive pillar bumps being less than 10% may mean that the bump density of the plurality of conductive pillar bumps is within a tolerance threshold of 10%.

In an aspect, the encapsulant layer may be disposed between the plurality of conductive bumps using the MUF process. As described above, the MUF process is performed without pulling a CUF material around the plurality of conductive pillar bumps, as in the CUF process. As such, the exposed die packaging structure will not include a CUF material around any of the plurality of conductive pillar bumps.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A die packaging structure, comprising:
a semiconductor die;
an encapsulant layer disposed around the semiconductor die, wherein a backside surface of the semiconductor die is exposed; and
a conductive layer coupled to the semiconductor die, the conductive layer comprising a plurality of conductive pillar bumps, wherein a bump density of the plurality of conductive pillar bumps is greater than 5%,
wherein the encapsulant layer is further disposed between the plurality of conductive bumps, and wherein the encapsulant layer is disposed between the plurality of conductive bumps using a mold underfill (MUF) process.

2. The die packaging structure of claim 1, further comprising:
an insulating layer; and
a plurality of package balls, wherein the plurality of conductive bumps are conductively coupled to the plurality of package balls by vias in the insulating layer.

3. The die packaging structure of claim 1, wherein the plurality of conductive pillar bumps comprise a plurality of copper pillar bumps.

4. The die packaging structure of claim 1, wherein the bump density of the plurality of conductive pillar bumps being greater than 5% comprises the bump density of the plurality of conductive pillar bumps being within a tolerance threshold of 5%.

5. The die packaging structure of claim 1, wherein the bump density of the plurality of conductive pillar bumps is less than 10%.

6. The die packaging structure of claim 5, wherein the bump density of the plurality of conductive pillar bumps being less than 10% comprises the bump density of the plurality of conductive pillar bumps being within a tolerance threshold of 10%.

7. The die packaging structure of claim 1, wherein the MUF process is performed without pulling a capillary underfill (CUF) material around the plurality of conductive pillar bumps.

8. The die packaging structure of claim 1, wherein the exposed die packaging structure does not include a CUF material around any of the plurality of conductive pillar bumps.

9. The die packaging structure of claim 1, wherein:
the bump density comprises a total bump area divided by an area of the semiconductor die,
the total bump area comprises a number of the plurality of conductive pillar bumps multiplied by an area of a conductive pillar bump of the plurality of conductive pillar bumps,
the area of the semiconductor die comprises a length of the semiconductor die multiplied a width of the semiconductor die.

10. The die packaging structure of claim 1, wherein the plurality of conductive pillar bumps are evenly distributed under the semiconductor die.

11. A method for forming a die packaging structure, comprising:
providing a semiconductor die;
forming a conductive layer coupled to the semiconductor die, the conductive layer comprising a plurality of conductive pillar bumps, wherein a bump density of the plurality of conductive pillar bumps is greater than 5%; and
forming an encapsulant layer around the semiconductor die, wherein a backside surface of the semiconductor die is exposed, and wherein forming the encapsulant layer further comprises inserting the encapsulant layer between the plurality of conductive bumps using a mold underfill (MUF) process.

12. The method of claim 11, further comprising:
providing an insulating layer; and
forming a plurality of package balls, wherein the plurality of conductive bumps are conductively coupled to the plurality of package balls by vias in the insulating layer.

13. The method of claim 11, wherein the plurality of conductive pillar bumps comprise a plurality of copper pillar bumps.

14. The method of claim 11, wherein the bump density of the plurality of conductive pillar bumps being greater than 5% comprises the bump density of the plurality of conductive pillar bumps being within a tolerance threshold of 5%.

15. The method of claim 11, wherein the bump density of the plurality of conductive pillar bumps is less than 10%.

16. The method of claim 15, wherein the bump density of the plurality of conductive pillar bumps being less than 10% comprises the bump density of the plurality of conductive pillar bumps being within a tolerance threshold of 10%.

17. The method of claim 11, wherein the MUF process is performed without pulling a capillary underfill (CUF) material around the plurality of conductive pillar bumps.

18. The method of claim 11, wherein the die packaging structure does not include a CUF material around any of the plurality of conductive pillar bumps.

19. The method of claim 11, wherein:
the bump density comprises a total bump area divided by an area of the semiconductor die,
the total bump area comprises a number of the plurality of conductive pillar bumps multiplied by an area of a conductive pillar bump of the plurality of conductive pillar bumps,
the area of the semiconductor die comprises a length of the semiconductor die multiplied a width of the semiconductor die.

20. The method of claim 11, wherein the plurality of conductive pillar bumps are evenly distributed under the semiconductor die.

21. An apparatus, comprising:
a semiconductor means;
a means for encapsulating disposed around the semiconductor means, wherein a backside surface of the semiconductor means is exposed; and
a means for conducting coupled to the semiconductor means, the means for conducting comprising a plurality of conductive pillar bumps, wherein a bump density of the plurality of conductive pillar bumps is greater than 5%,
wherein the means for encapsulating is further disposed between the plurality of conductive bumps, and wherein the means for encapsulating is disposed between the plurality of conductive bumps using a mold underfill (MUF) process.

22. The apparatus of claim 21, further comprising:
an insulating layer; and
a plurality of package balls, wherein the plurality of conductive bumps are conductively coupled to the plurality of package balls by vias in the insulating layer.

23. The apparatus of claim 21, wherein the plurality of conductive pillar bumps comprise a plurality of copper pillar bumps.

24. The apparatus of claim 21, wherein the bump density of the plurality of conductive pillar bumps being greater than 5% comprises the bump density of the plurality of conductive pillar bumps being within a tolerance threshold of 5%.

25. The apparatus of claim 21, wherein the bump density of the plurality of conductive pillar bumps is less than 10%.

26. The apparatus of claim 25, wherein the bump density of the plurality of conductive pillar bumps being less than 10% comprises the bump density of the plurality of conductive pillar bumps being within a tolerance threshold of 10%.

27. The apparatus of claim 21, wherein the apparatus does not include a CUF material around any of the plurality of conductive pillar bumps.

28. The apparatus of claim 21, wherein:
the bump density comprises a total bump area divided by an area of the semiconductor means,
the total bump area comprises a number of the plurality of conductive pillar bumps multiplied by an area of a conductive pillar bump of the plurality of conductive pillar bumps,
the area of the semiconductor means comprises a length of the semiconductor means multiplied a width of the semiconductor means.

29. The apparatus of claim 21, wherein the plurality of conductive pillar bumps are evenly distributed under the semiconductor means.

30. A non-transitory computer-readable medium storing computer-executable instructions for forming a die packaging structure, the computer-executable instructions comprising:
at least one instruction for causing a machine to provide a semiconductor die;
at least one instruction for causing a machine to form a conductive layer coupled to the semiconductor die, the conductive layer comprising a plurality of conductive pillar bumps, wherein a bump density of the plurality of conductive pillar bumps is greater than 5%; and
at least one instruction for causing a machine to form an encapsulant layer around the semiconductor die, wherein a backside surface of the semiconductor die is exposed, and wherein the at least one instruction for causing a machine to form the encapsulant layer comprises at least one instruction for causing a machine to insert the encapsulant layer between the plurality of conductive bumps using a mold underfill (MUF) process.
